(19) United States
(12) Patent Application Publication
(10) Pub. No.: US 2013/0292832 A1
(43) Pub. Date: Nov. 7, 2013

(54) SEMICONDUCTOR PACKAGE AND FABRICATION METHOD THEREOF

(71) Applicants: Shao-Tzu Tang, Taichung (TW); Chi-Ching Ho, Taichung (TW); Ying-Chou Tsai, Taichung (TW); Chang-Yi Lan, Taichung (TW)

(72) Inventors: Shao-Tzu Tang, Taichung (TW); Chi-Ching Ho, Taichung (TW); Ying-Chou Tsai, Taichung (TW); Chang-Yi Lan, Taichung (TW)

(73) Assignee: SILICONWARE PRECISION INDUSTRIES CO., LTD., Taichung (TW)

(21) Appl. No.: 13/584,965

(22) Filed: Aug. 14, 2012

(30) Foreign Application Priority Data
May 7, 2012 (TW) 101116157

(51) Int. Cl. H01L 23/498; H01L 21/60

(52) U.S. Cl. 257/738; 438/127; 257/E23.069; 257/E21.509

(57) ABSTRACT

A semiconductor package includes: a first insulating layer; a plurality of first conductive elements disposed in the first insulating layer; a first circuit layer formed on the first insulating layer; a semiconductor chip disposed on the first insulating layer; and an encapsulant formed on the first insulating layer and encapsulating the semiconductor chip. The first conductive elements that are bonding wires have a small diameter and thus occupy desired limited space on the first insulating layer. Therefore, more space is available for the first circuit layer.

### BACKGROUND OF THE INVENTION

1. Field of the Invention

The present invention relates to semiconductor packages and fabrication methods thereof, and, more particularly, to a semiconductor package and a fabrication method thereof for improving the product reliability and circuit density.

2. Description of Related Art

Semiconductor packaging technologies have been continuously improved to meet the miniaturization and system integration requirements of electronic products. For example, a fabrication method of a small leadless package (SLP) is disclosed by U.S. Pat. No. 7,435,680, as shown in FIGS. 1A to 1F.

Referring to FIG. 1A, a carrier 10 having a plurality of conductive pads 100 is provided.

Referring to FIG. 1B, a dielectric layer 12 made of prepreg (PP) is formed on the carrier 10, and a plurality of vias 120 are formed in the dielectric layer 12 in a laser drilling process so as to expose the conductive pads 100, respectively.

Referring to FIG. 1C, by performing an electroplating process, a copper layer is formed on the dielectric layer 12 and conductive vias 11 are formed in the vias 120. Then, the copper layer is etched to form a circuit layer 13 that is electrically connected to the conductive pads 100 through the conductive vias 11.

Referring to FIG. 1D, an insulating protection layer 14 is formed on the dielectric layer 12 and the circuit layer 13, and a plurality of openings 140 are formed in the insulating protection layer 14 such that a portion of the circuit layer 13 is exposed through the openings 140 to serve as conductive pads 130.

Referring to FIG. 1E, a semiconductor chip 15 is disposed on the insulating protection layer 14 and electrically connected to the conductive pads 130 in the openings 140 through a plurality of bonding wires 150. Then, an encapsulant 16 is formed on the insulating protection layer 14 for encapsulating the conductive pads 130, the semiconductor chip 15 and the bonding wires 150.

Referring to FIG. 1F, the carrier 10 is removed to expose the conductive pads 100. Further, a plurality of solder balls (not shown) can be mounted on the conductive pads 100, respectively, for electrically connecting an electronic device such as a circuit board (not shown).

Referring to FIG. 1F′, in another embodiment a built-up structure 17 is formed on the circuit layer 13 and the dielectric layer 12, and then the insulating protection layer 14 is formed on the built-up structure 17. The built-up structure 17 has at least a dielectric layer 170, a circuit layer 171 formed on the dielectric layer 170, and a plurality of conductive vias 172 formed in the dielectric layer 170 for electrically connecting the circuit layers 13 and 171. The insulating protection layer 14 is formed on the uppermost dielectric layer 170, and a portion of the circuit layer 171 is exposed through the openings of the insulating protection layer 14 to serve as wire bonding pads.

In the above-described method of the semiconductor package 1, 1′, a clean process is required for removing excess debris generated in the vias 120 of the dielectric layer 12 during the laser drilling process. However, the excess debris is difficult to be removed completely. Consequently, delamination can easily occur to the circuit layer 13, 171 so that electrical performance tends to be poor.

Further, the vias 120 have a diameter of approximately 60 to 80 um, and thus occupy much space on the dielectric layer 12 such that little space is left available for the circuit layer 13.

Furthermore, since the vias 120 in the upper layer and the conductive vias 172a of the built-up structure 17 in the lower layer are formed by the laser drilling process, the vias 120 and 172a must be arranged in a staggering pattern, thus lengthening the conductive path of the circuit layers 13 and 171 and adversely affecting the electrical performance.

Therefore, there is a need to provide a semiconductor package and a fabrication method thereof so as to overcome the above-described drawbacks.

### SUMMARY OF THE INVENTION

In view of the above-described drawbacks, the present invention provides a semiconductor package, which comprises: a built-up structure having a first insulating layer having opposite first and second surfaces, a plurality of first conductive elements formed in the first insulating layer and partially exposed from the first surface of the first insulating layer, and a first circuit layer formed on the first insulating layer and electrically connected to the first conductive elements; a semiconductor chip disposed on the built-up structure and electrically connected to the first circuit layer; and an encapsulant formed on the built-up structure for encapsulating the semiconductor chip.

The present invention further provides a fabrication method of a semiconductor package, which comprises the steps of: forming a built-up structure, which comprises: forming a plurality of first conductive elements on a carrier; forming on the carrier a first insulating layer that encapsulates the first conductive elements, wherein the first insulating layer has opposite first and second surfaces, the first insulating layer is attached to the carrier through the second surface thereof, and the first conductive elements are partially exposed from the first surface of the first insulating layer; and forming on the first surface of the first insulating layer a first circuit layer electrically connected to the first conductive elements; disposing a semiconductor chip on the built-up structure and electrically connecting the semiconductor chip and the first circuit layer; forming an encapsulant on the built-up structure for encapsulating the semiconductor chip; and removing the carrier.

In the above-described fabrication method, the carrier can be a metal plate or a glass fiber sheet (FR4).

The above-described fabrication method can further comprise thinning the first insulating layer by a grinding process so as to partially expose the first conductive elements from the first surface of the first insulating layer.

The above-described fabrication method can further comprise performing a singulation process after removing the carrier.

In the above-described fabrication method, the carrier can have a plurality of conductive pads so as for the first conductive elements to be formed thereon. After the carrier is removed, the conductive pads can be exposed from the second surface of the first insulating layer so as for solder balls to be mounted thereon.

In the above-described package and fabrication method, exposed surfaces of the first conductive elements can be flush with the first surface of the first insulating layer.

In the above-described package and fabrication method, the first conductive elements can be ball bonds or wedge bonds.

In the above-described fabrication method, forming the built-up structure further comprises: forming a plurality of second conductive elements on the first circuit layer; forming on the first surface of the first insulating layer a second insulating layer encapsulating the second conductive elements and the first circuit layer; and forming on the second insulating layer a second circuit layer electrically connected to the first circuit layer through the second conductive elements. The second conductive elements are ball bonds or wedge bonds.

In the above-described package and fabrication method, the first and second insulating layers can be made of a molding compound, prepreg (PP) or ABF (Ajinomoto build up film).

Before disposing the semiconductor chip, the above-described fabrication method can further comprise forming an insulating protection layer on the built-up structure and forming a plurality of openings in the insulating protection layer for exposing a portion of the first circuit layer. As such, the semiconductor chip is disposed on the insulating protection layer.

Therefore, by forming the first conductive elements first and then forming the first insulating layer, the present invention dispenses with the laser drilling process as required in the prior art. Consequently, the present invention avoids the cleaning process that is otherwise required in the prior art for removing excess debris and effectively prevents delamination of the first circuit layer such that the electrical performance can be improved.

Further, since the first conductive elements, such as bonding wires, have a width of approximately 18 um that is greatly less than the diameter of the conventional conductive vias, the first conductive elements occupy far less space on the first surface of the first insulating layer such that more space is available for the first circuit layer.

Furthermore, in the built-up structure, the binding wires (the first conductive elements) in the upper and lower layers of bonding wires can be arranged in alignment instead of in a staggering pattern, thereby shortening the conductive path of the first circuit layer and improving the electrical performance.

### BRIEF DESCRIPTION OF DRAWINGS

FIGS. 1A to 1F are schematically cross-sectional views showing a fabrication method of a semiconductor package according to the prior art, wherein FIG. 1F′ shows another embodiment of FIG. 1F; and

FIGS. 2A to 2I are schematically cross-sectional views showing a fabrication method of a semiconductor package according to the present invention, wherein FIG. 2B′ shows another embodiment of FIG. 2B, FIG. 2H′ shows another embodiment of FIG. 2H, and FIGS. 2I′ and 2I″ show other embodiments of FIG. 2I.

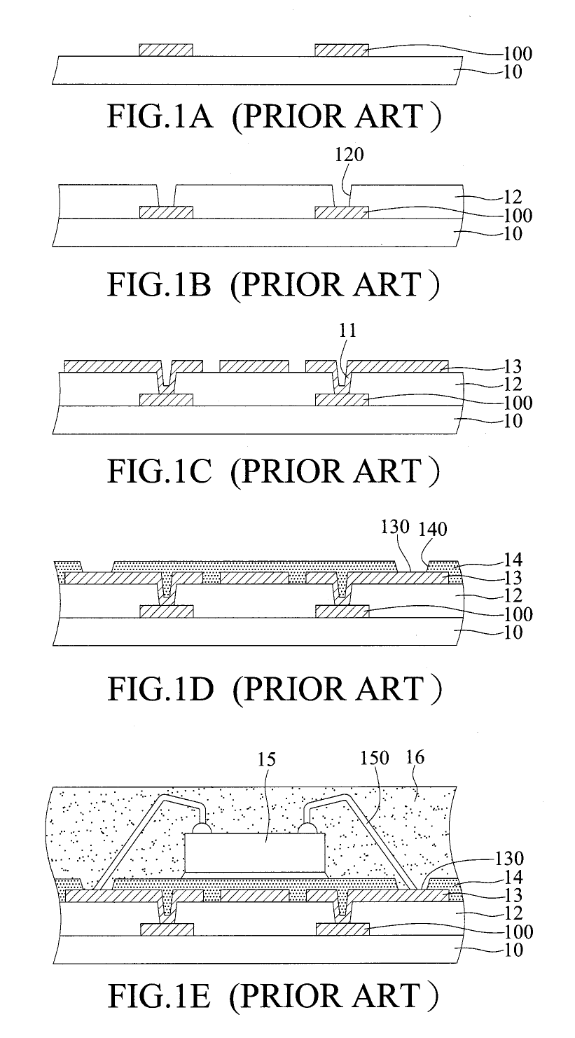

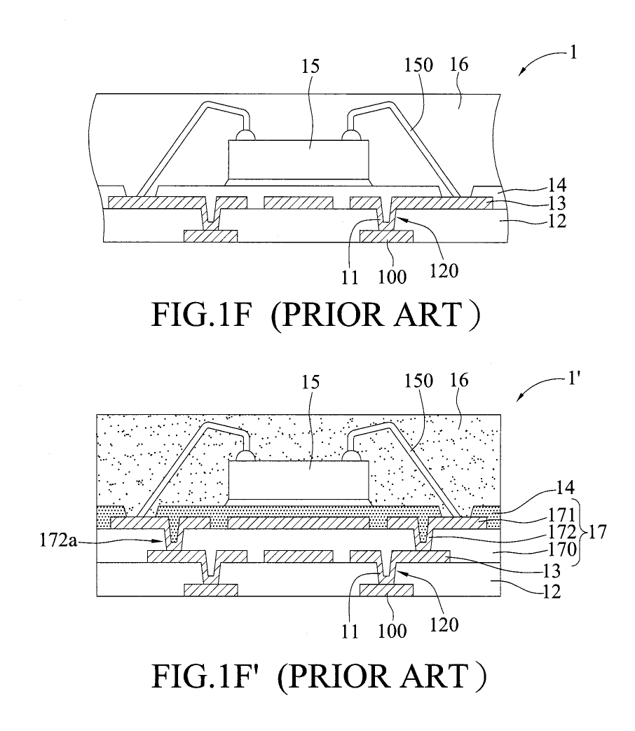

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “upper”, “lower”, “one” etc. are merely for illustrative purpose and should not be construed to limit the scope of the present invention.

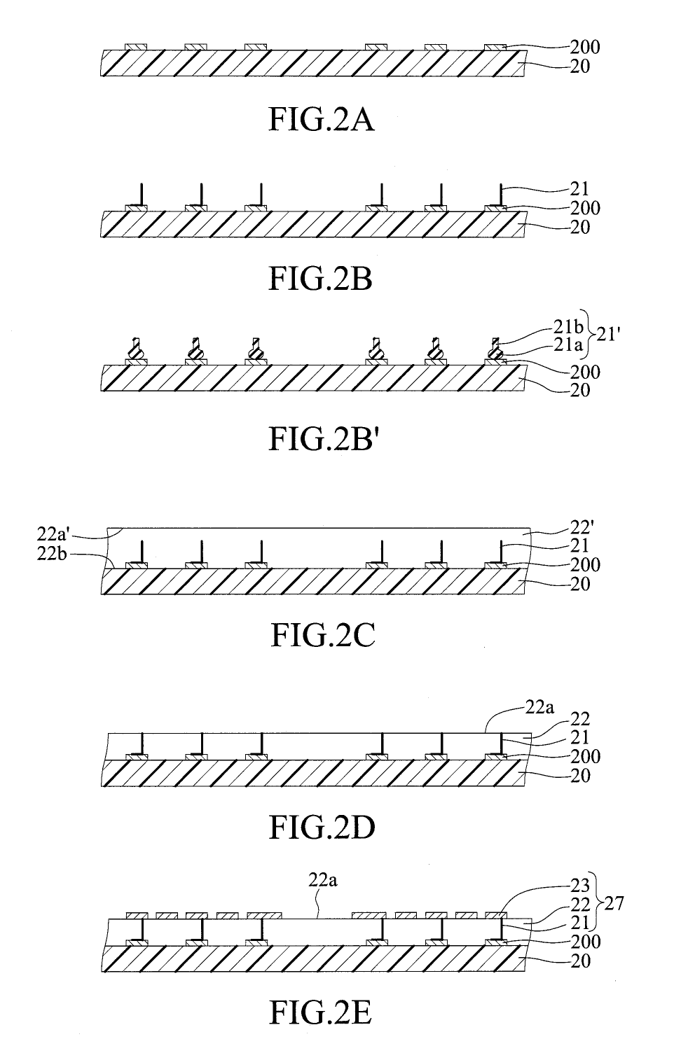

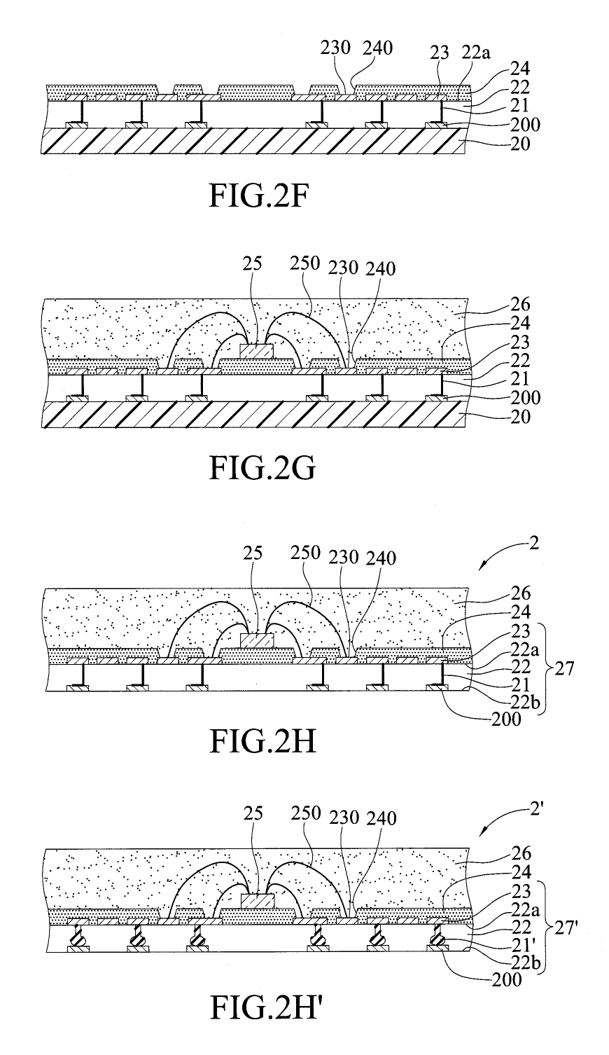

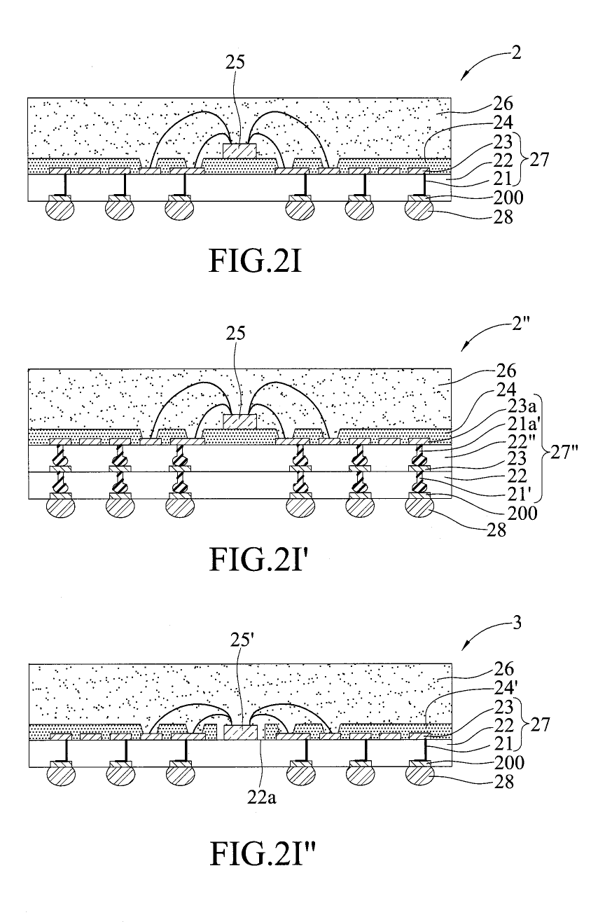

FIGS. 2A to 2I are schematically cross-sectional views showing a fabrication method of a semiconductor package 2 according to the present invention.

Referring to FIG. 2A, a carrier 20 having a plurality of conductive pads 200 thereon is provided. In the present embodiment, the carrier 20 can be a metal plate or a glass fiber sheet (FR4).

Referring to FIG. 2B, a plurality of first conductive elements 21 that may be bonding wires are formed on the conductive pads 200, respectively.

In the present embodiment, the first conductive elements 21 are wedge bonds. The first conductive elements 21 can be made of copper, gold, silver or aluminum. In another embodiment, referring to FIG. 2B′, the first conductive elements 21′ are ball bonds. That is, each of the first conductive elements 21′ has a ball portion 21a for connecting a corresponding one of the conductive pads 200 and a segment 21b extending from the ball portion 21a.

Referring to FIG. 2C, continued from FIG. 2B, a first insulating layer 22′ is formed on the carrier 20 for encapsulating the conductive pads 200 and the first conductive elements 21.

In the present embodiment, the first insulating layer 22′ has a first surface 22a′ and a second surface 22b opposite to the first surface 22a′ and attached to the carrier 20 and the conductive pads 200.

The first insulating layer 22′ can be made of a molding compound, prepreg (PP) or ABF (Ajinomoto build up film).

Referring to FIG. 2D, the first insulating layer 22′ is thinned by a grinding process such that surfaces of the first conductive elements 21 are flush with the first surface 22a of the first insulating layer 22′. As such, the first conductive elements 21 are partially exposed from the first surface 22a of the first insulating layer 22.

Referring to FIG. 2E, a copper layer is formed on the first surface 22a of the first insulating layer 22 by an electroplating process and then etched to form a first circuit layer 23 electrically connected to the first conductive elements 21. The first insulating layer 22, the first conductive elements 21 and the first circuit layer 23 form a built-up structure 27.

Therefore, by forming the first conductive elements 21 first and then forming the first insulating layer 22′ and thinning the first insulating layer 22′, the present invention dispenses with the laser drilling process as required in the prior art. Consequently, the present invention avoids the cleaning process that is otherwise required in the prior art for removing excess debris and effectively prevents delamination of the first circuit layer 23 so that the electrical performance can be improved.

Further, since the first conductive elements, bonding wires, have a width of approximately 18 um that is greatly less than the diameter of the conventional conductive vias, the first conductive elements 21 occupy merely little space of the first surface 22a of the first insulating layer 22, thereby leaving more space available for the first circuit layer 23.

Referring to FIG. 2F, an insulating protection layer 24 is formed on the first surface 22a of the insulating layer 22 and the first circuit layer 23, and a plurality of openings 240 are formed in the insulating protection layer 24 such that a portion of the first circuit layer 23 is exposed through the openings 240 to serve as conductive pads 230.

Referring to FIG. 2G, a semiconductor chip 25 is disposed on the insulating protection layer 24 and electrically connected to the conductive pads 230 through bonding wires 250.

In the present embodiment, the conductive pads 230 are wire bonding pads. In other embodiments, the conductive pads 230 can be flip-chip bonding pads, on which conductive bumps (not shown) can be mounted for electrically connecting the semiconductor chip 25 and the first circuit layer 23. Further, the bonding wires 250 can be gold wires or copper wires.

Subsequently, an encapsulant 26 is formed on the insulating protection layer 24 by a molding process so as to encapsulate the first circuit layer 23, the semiconductor chip 25 and the bonding wires 250 (or conductive bumps).

Referring to FIG. 2H or 2H′, the carrier 20 is removed to expose the conductive pads 200.

Referring to FIG. 2I, a plurality of solder balls 28 are mounted on the conductive pads 200 (or ball portions 21a), respectively, and then a singulation process is performed according to the practical need. Thereafter, an electronic device such as a circuit board (not shown) can be mounted on the solder balls 28.

Further, referring to FIG. 2I′, before the formation of the insulating protection layer 24, a plurality of second conductive elements 21a′ are formed on the first circuit layer 23 and then a second insulating layer 22″ is formed on first surface 22a of the first insulating layer 22 for encapsulating the second conductive elements 21a′ and the first circuit layer 23. Further, a second circuit layer 23a is formed on the second insulating layer 22″ and electrically connected to the first circuit layer 23 through the second conductive elements 21a′. Therefore, the built-up structure 27″ further has the second insulating layer 22″ and the second conductive elements 21a′.

In the present embodiment, the second conductive elements 21a′ are bonding wires. The insulating protection layer 24 is formed on the uppermost second insulating layer 22″ and a portion of the second circuit layer 23a is exposed from the openings of the insulating protection layer 24 so as to serve as wire bonding pads or flip-chip bonding pads.

The second insulating layer 22″ can be made of a molding compound, prepreg (PP) or ABF (Ajinomoto build up Film).

Therefore, by replacing the conventional conductive vias with the bonding wires, i.e., the first conductive elements 21, 21′ and the second conductive elements 21a′, the present invention allows bonding wires in the upper and lower layers, i.e., the first conductive elements 21, 21′ and the second conductive elements 21a′, to be arranged in alignment instead of in a staggering pattern, thereby shortening the conductive path of the first and second circuit layers 23, 23a and thus improving the electrical performance.

In another embodiment, referring to FIG. 2I″, when an insulating protection layer 24′ is formed, a portion of the first surface 22a of the first insulating layer 22 can be exposed for a semiconductor chip 25′ to be mounted thereon. Alternatively, the semiconductor chip 25′ can be disposed on the second insulating layer 22″ according to the practical requirement.

The present invention further provides a semiconductor package 2, 2′, which has: a built-up structure 27, 27′; an insulating protection layer 24 formed on the built-up structure 27, 27′; a semiconductor chip 25 disposed on the built-up structure 27, 27′; and an encapsulant 26 formed on the insulating protection layer 24 for encapsulating the semiconductor chip 25.

The built-up structure 27, 27′ has a first insulating layer 22 having a first surface 22a and a second surface 22b opposite to the first surface 22a, a plurality of first conductive elements 21, 21′ formed in the first insulating layer 22, and a first circuit layer 23 formed on the first surface 22a of the first insulating layer 22.

The second surface 22b of the first insulating layer 22 has a plurality of conductive pads 200 bonded to the first conductive elements 21, 21′. A plurality of solder balls 28 are mounted on the conductive pads 200, respectively. The surfaces of the conductive pads 200 are flush with the second surface 22b of the first insulating layer 22. The first insulating layer 22 can be made of a molding compound, prepreg (PP) or ABF (Ajinomoto build up film).

The surfaces of the first conductive elements 21, 21′ are flush with the first surface 22a of the first insulating layer 22 such that the first conductive elements 21, 21′ are exposed from the first surface 22a. The first conductive elements 21, 21′ are bonding wires, which have ball bonds or wedge bonds.

The first circuit layer 23 is electrically connected to the first conductive elements 21, 21′.

The insulating protection layer 24 is formed on the first insulating layer 22 and has a plurality of openings 240 for exposing a portion of the first circuit layer 23.

The semiconductor chip 25 is disposed on the insulating protection layer 24 and electrically connected to the first circuit layer 23 through a plurality of bonding wires 250 or conductive bumps (not shown).

The encapsulant 26 encapsulates the semiconductor chip 25 and the bonding wires 250 (or conductive bumps).

In the semiconductor package 2″, the built-up structure 27″ further has at least a second insulating layer 22″ formed on the first insulating layer 22, a plurality of second conductive elements 21a′ formed in the second insulating layer 22″ and a second circuit layer 23a formed on the second insulating layer 22″. The second conductive elements 21a′ electrically connect the first and second circuit layers 23, 23a and a portion of the second circuit layer 23a is exposed through the openings 240 so as to be electrically connected to the semiconductor chip 25 through bonding wires 250 or conductive bumps. The second conductive elements 21a′ can be bonding wires. The second insulating layer 22″ can be made of a molding compound, prepreg (PP) or ABF (Ajinomoto build up film).

In another semiconductor package 3, a portion of the first surface 22a of the first insulating layer 22 is exposed from an insulating protection layer 24′ so as for a semiconductor chip 25′ to be mounted thereon.

Therefore, by forming the conductive elements first and then forming the insulating layer, the present invention dispenses with the laser drilling process as required in the prior art. Consequently, the present invention avoids the cleaning process that is otherwise required in the prior art for removing excess debris and effectively prevents delamination of the circuit layer so that the electrical performance is improved.

Further, by replacing the conductive vias with the bonding wires, the present invention allows more space to be used for the circuit layer. Furthermore, in the built-up structure, the bonding wires in the upper and lower layers can be arranged in alignment instead of in a staggering pattern, thereby shortening the conductive path of the circuit layer and improving the electrical performance. Therefore, the product reliability is improved.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

1. A semiconductor package, comprising:
a built-up structure having a first insulating layer, a plurality of first conductive elements and a first circuit layer, wherein the first insulating layer has opposite first and second surfaces, the first conductive elements that are bonding wires are disposed in the first insulating layer, an end of each of the first conductive elements is exposed from the first surface of the first insulating layer, and the first circuit layer is formed on the first insulating layer and electrically connected to the first conductive elements;
a semiconductor chip disposed on the built-up structure and electrically connected to the first circuit layer; and
an encapsulant formed on the built-up structure for encapsulating the semiconductor chip.

2. The semiconductor package of claim 1, wherein the exposed ends of the first conductive elements are flush with the first surface of the first insulating layer.

3. The semiconductor package of claim 1, wherein the bonding wires have ball bonds or wedge bonds.

4. The semiconductor package of claim 1, wherein the second surface of the first insulating layer has a plurality of conductive pads electrically connected to the first conductive elements.

5. The semiconductor package of claim 4, wherein each of the conductive pads has a solder ball mounted thereon.

6. The semiconductor package of claim 4, wherein the conductive pads have surfaces flush with the second surface of the first insulating layer.

7. The semiconductor package of claim 1, wherein the built-up structure further has at least a second insulating layer formed on the first surface of the first insulating layer, a plurality of second conductive elements disposed in the second insulating layer, and a second circuit layer formed on the second insulating layer and electrically connected to the first circuit layer through the second conductive elements.

8. The semiconductor package of claim 7, wherein the second conductive elements are ball bonds or wedge bonds.

9. The semiconductor package of claim 7, wherein the second insulating layer is made of a molding compound, prepreg (PP) or ABF (Ajinomoto built-up film).

10. The semiconductor package of claim 1, wherein the first insulating layer is made of a molding compound, prepreg (PP) or ABF (Ajinomoto built-up film).

11. The semiconductor package of claim 1, further comprising an insulating protection layer formed on the built-up structure and having a plurality of openings for exposing a portion of the first circuit layer.

12. The semiconductor package of claim 11, wherein the semiconductor chip is disposed on the insulating protection layer.

13. A fabrication method of a semiconductor package, comprising the steps of:
forming a built-up structure, comprising:
forming on a carrier a plurality of first conductive elements;
forming a first insulating layer on the carrier to encapsulate the first conductive elements, wherein the first insulating layer has opposite first and second surfaces and is attached to the carrier through the second surface thereof, and the first conductive elements are exposed from the first surface of the first insulating layer; and
forming on the first surface of the first insulating layer a first circuit layer electrically connected to the first conductive elements;
disposing a semiconductor chip on the built-up structure and electrically connecting the semiconductor chip and the first circuit layer;
forming an encapsulant on the built-up structure for encapsulating the semiconductor chip; and
removing the carrier.

14. The fabrication method of claim 13, wherein the first conductive elements have surfaces flush with the first surface of the first insulating layer.

15. The fabrication method of claim 13, wherein the first conductive elements are ball bonds or wedge bonds.

16. The fabrication method of claim 13, further comprising thinning the first insulating layer by a grinding process so as to expose the first conductive elements from the first surface of the first insulating layer.

17. The fabrication method of claim 13, wherein forming the built-up structure further comprises: forming a plurality of second conductive elements on the first circuit layer; forming on the first surface of the first insulating layer a second insulating layer encapsulating the second conductive elements and the first circuit layer; and forming on the second insulating layer a second circuit layer electrically connected to the first circuit layer through the second conductive elements.

18. The fabrication method of claim 17, wherein the second conductive elements are ball bonds or wedge bonds.

19. The fabrication method of claim 17, wherein the second insulating layer is made of a molding compound, prepreg (PP) or ABF (Ajinomoto build up film).

20. The fabrication method of claim 13, wherein the first insulating layer is made of a molding compound, prepreg (PP) or ABF (Ajinomoto build up film).

21. The fabrication method of claim 13, wherein the carrier is a metal plate or a glass fiber sheet (FR4).

22. The fabrication method of claim 13, wherein the carrier has a plurality of conductive pads on which the first conductive elements are formed.

23. The fabrication method of claim 22, wherein after the carrier is removed, the conductive pads are exposed from the second surface of the first insulating layer.

24. The fabrication method of claim 23, further comprising mounting a plurality of solder balls on the conductive pads, respectively.

25. The fabrication method of claim 13, further comprising, prior to disposing the semiconductor chip, forming an insulating protection layer on the built-up structure and forming a plurality of openings in the insulating protection layer for exposing a portion of the first circuit layer.

26. The fabrication method of claim 25, wherein the semiconductor chip is disposed on the insulating protection layer.

27. The fabrication method of claim 13, further comprising, after removing the carrier, performing a singulation process.
